(19) United States
(12) Patent Application Publication
(10) Pub. No.: US 2023/0180384 A1
(43) Pub. Date: Jun. 8, 2023

(54) METAL-CLAD LAMINATE

(71) Applicant: SHIN-ETSU POLYMER CO., LTD., Tokyo (JP)

(72) Inventors: Kazuyoshi YOSHIDA, Saitama (JP); Wataru KATAGIRI, Saitama (JP)

(21) Appl. No.: 17/995,309

(22) PCT Filed: Feb. 26, 2021
(86) PCT No.: PCT/JP2021/007327

§ 371 Date: Oct. 2, 2022

(30) Foreign Application Priority Data
Apr. 3, 2020 (JP) 2020-067695

(51) Int. Cl. H05K 1/03; C23C 14/20; C23C 14/34

(52) U.S. Cl. CPC H05K 1/0373; C23C 14/205; C23C 14/34; H05K 2201/0355; H05K 2201/068; H05K 2201/0245; H05K 2201/0209

(57) ABSTRACT

There is provided a metal-clad laminate in which the transmission loss of electrical signals can be reduced, a finer pitch of a circuit pattern is possible, a high precision and fine circuit can be formed, and the close adhesiveness of the metal film is excellent. The metal-clad laminate includes a coating film and a metal film laminated on a base material film in this order, wherein the metal film is a metal film formed by at least any formation method of plating, sputtering, and vapor deposition, and a surface roughness (Rz) of the coating film is 1 μm or less.

### RELATED APPLICATIONS

The present application is a National Phase of International Application Number PCT/JP2021/007327 filed Feb. 26, 2021, which claims the benefit of priority from Japanese Patent Application No. 2020-067695, filed on Apr. 3, 2020.

### TECHNICAL FIELD

The present invention relates to a metal-clad laminate.

### BACKGROUND ART

In recent years, with higher communication rates and larger capacity in communication equipment typified by smartphones, lower loss of electrical signals, a finer pitch of a circuit pattern, and the formation of a high precision and fine circuit are required of the circuit boards used in the communication equipment.

The same performance as the circuit boards is also required of metal-clad laminates that are the main materials of circuit boards, so-called metal-clad laminates (for example, copper-clad laminates (CCLs)) in which a metal film is placed and laminated on the surface of a base material film including an insulating resin.

Various improved metal-clad laminates (for example, copper-clad laminates (CCLs)) are proposed (for example, see Patent Literature 1).

### CITATION LIST

### Patent Literature

Patent Literature 1: Japanese Patent Laid-Open No. 2011-14801

### SUMMARY OF INVENTION

### Technical Problem

In order to reduce the transmission loss of electrical signals, the surface of a metal film that forms a transmission line for electrical signals being smooth is effective. But when the surface of the metal film is smooth, the close adhesiveness (adhesiveness) between the metal film and other layers is a problem.

Accordingly, there is a demand for the provision of a metal-clad laminate in which the transmission loss of electrical signals can be reduced, and the close adhesiveness between the metal film and the base material film is excellent.

But there has not been provided so far a metal-clad laminate having a metal film having a smooth surface that can reduce the transmission loss of electrical signals in which the close adhesiveness of the metal film is good, and further a finer pitch of a circuit pattern is possible, a high precision and fine circuit can be formed, and all these requirements can be sufficiently satisfied.

Accordingly it is an object of the present invention to provide a metal-clad laminate having a metal film having a smooth surface that can reduce the transmission loss of electrical signals in which the close adhesiveness of the metal film is good, a finer pitch of a circuit pattern is possible, and a high precision and fine circuit can be formed.

### Solution to Problem

The present inventors have diligently repeated studies in order to solve the problem, and as a result found that the problem can be solved by making the metal film a metal film formed by at least any formation method of plating, sputtering, and vapor deposition and disposing a coating film having a particular surface roughness (Rz) between the metal film and a base material film, and completed the present invention.

The present invention encompasses the following aspects.

[1] A metal-clad laminate including a coating film and a metal film laminated on a base material film in this order, wherein

the metal film is a metal film formed by at least any formation method of plating, sputtering, and vapor deposition, and

a surface roughness (Rz) of the coating film is 1 μm or less.

[2] The metal-clad laminate according to [1], wherein the coating film and the metal film are laminated on each of both sides of the base material film, and wherein the metal-clad laminate includes a metal film, a coating film, a base material film, a coating film, and a metal film laminated in order.
[3] The metal-clad laminate according to [1] or [2], wherein a surface roughness (Rz) of the base material film is 1 μm or more and 10 μm or less.
[4] The metal-clad laminate according to any of [1] to [3], wherein a surface roughness (Rz) of the metal film is 0.5 μm or less.
[5] The metal-clad laminate according to any of [1] to [4], wherein the coating film includes a thermosetting resin.
[6] The metal-clad laminate according to any of [1] to [5], wherein the coating film includes at least any of an epoxy resin, a polyimide resin, or a bismaleimide resin.
[7] The metal-clad laminate according to any of [1] to [6], wherein a film thickness of the coating film is not less than the surface roughness (Rz) of the base material film×0.8.
[8] The metal-clad laminate according to any of [1] to [7], wherein a film thickness of the metal film is 0.05 μm or more and 10 μm or less.
[9] The metal-clad laminate according to any of [1] to [8], wherein a relative dielectric constant of the base material film is 3.5 or less, and a dielectric loss tangent of the base material film is 0.004 or less.
[10] The metal-clad laminate according to any of [1] to [9], wherein a relative dielectric constant of the coating film is 3.5 or less, and a dielectric loss tangent of the coating film is 0.004 or less.
[11] The metal-clad laminate according to any of [1] to [10], wherein a coefficient of thermal expansion (CTE) of the base material film is 50 ppm or less.
[12] The metal-clad laminate according to any of [1] to [11], wherein the base material film is a liquid crystal polymer (LCP) film, a polyether ether ketone (PEEK) film, a tetrafluoroethylene perfluoroalkyl (PFA) film, or a polyphenylene sulfide (PPS) film.
[13] The metal-clad laminate according to any of [1] to [12], wherein the base material film contains a filler.
[14] The metal-clad laminate according to any of [1] to [13], wherein the filler includes at least any of mica, talc, boron nitride (BN), magnesium oxide, and silica.
[15] The metal-clad laminate according to any of [1] to [14], wherein the filler has a plate-like shape.
[16] The metal-clad laminate according to any of [1] to [15], wherein an aspect ratio of the filler is 5 or more and 500 or less.
[17] The metal-clad laminate according to any of [1] to [16], wherein an average particle diameter of the filler is 20 μm or less.
[18] The metal-clad laminate according to any of [1] to [17], wherein the coating film contains a filler.
[19] The metal-clad laminate according to any of [1] to [18], wherein the metal film is a metal film of copper.
[20] The metal-clad laminate according to any of [1] to [19], wherein a surface of the base material film, the coating film, or the base material film and the coating film is corona-treated, plasma-treated, or ultraviolet-treated.

### Advantageous Effects of Invention

According to the present invention, it is possible to provide a metal-clad laminate having a metal film having a smooth surface that can reduce the transmission loss of electrical signals in which the close adhesiveness of the metal film is good, a finer pitch of a circuit pattern is possible, and a high precision and fine circuit can be formed.

### BRIEF DESCRIPTION OF DRAWINGS

FIG. 1 is a cross-sectional view showing one example of the configuration of the metal-clad laminate of the present invention.

FIG. 2 is a cross-sectional view showing another example of the configuration of the metal-clad laminate of the present invention.

### DESCRIPTION OF EMBODIMENTS

The metal-clad laminate of the present invention will be described in detail below, but the description of the configuration requirements described below provides one example as one embodiment of the present invention, and the present invention is not specified to these contents.

The definitions of the following terms are applied herein and to the claims.

The film thickness of a base material film, a coating film, a metal film, or the like is a value obtained by observing a cross section to be measured using a microscope, measuring thickness in five places, and averaging the measured thickness.

(Metal-Clad Laminate)

The metal-clad laminate of the present invention includes a coating film and a metal film laminated on a base material film in this order.

The metal film is a metal film formed by at least any formation method of plating, sputtering, and vapor deposition.

The surface roughness (Rz) of the coating film is 1 μm or less.

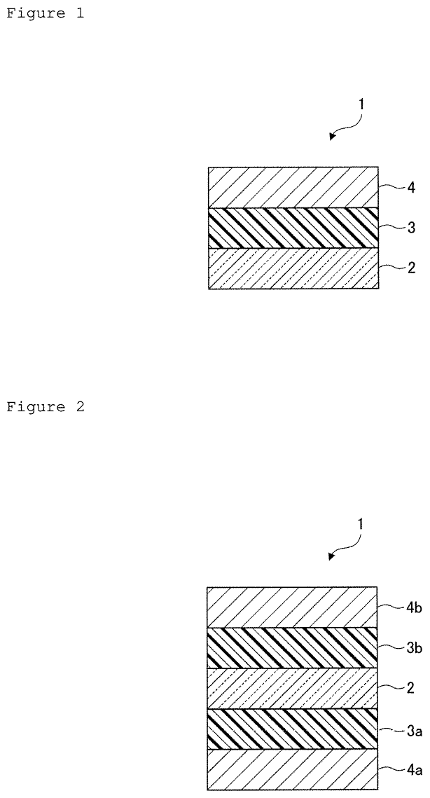

FIG. 1 is a cross-sectional view showing one example of the configuration of the metal-clad laminate of the present invention.

A metal-clad laminate 1 has a base material film 2, a coating film 3, and a metal film 4, and includes them laminated in this order.

In the metal-clad laminate of the present invention, the coating film and the metal film may be laminated on each of both sides of the base material film.

Another example of the configuration of the metal-clad laminate of the present invention is shown in FIG. 2.

The metal-clad laminate 1 of the present invention shown in FIG. 2 includes a metal film 4a, a coating film 3a, a base material film 2, a coating film 3b, and a metal film 4b laminated in this order.

<Base Material Film>

In the present invention, the base material film is not limited and can be appropriately selected according to the purpose, and examples of the base material film include an insulating resin film such as a polyimide film, a polyetheretherketone (PEEK) film, a polyetherketone (PEK) film, a polyetherketoneketone (PEKK) film, a tetrafluoroethylene-perfluoroalkyl vinyl ether copolymer (PFA) film, a tetrafluoroethylene-hexafluoropropylene copolymer (FEP) film, a tetrafluoroethylene-ethylene copolymer (ETFE) film, a polyphenylene sulfide (PPS) film, an aramid film, a polyethylene naphthalate film, and a liquid crystal polymer film (LCP), and a film of a mixture thereof. Among these, a polyether ether ketone (PEEK) film, a tetrafluoroethylene-perfluoroalkyl vinyl ether copolymer (PFA) film, a polyphenylene sulfide (PPS) film, and a liquid crystal polymer (LCP) film are preferred from the viewpoint of adhesiveness and electrical characteristics.

A filler can be contained in the base material film. The filler will be described in detail below.

<<Filler>>

The base material film can include a filler in order to provide various functions such as the adjustment of the strength, insulating properties, heat resistance, and coefficient of thermal expansion (CTE) of the base material. Examples of the filler include an inorganic filler and an organic filler, and these can be used singly or in combination.

Examples of the inorganic filler include mica, talc, boron nitride, magnesium oxide, silica, diatomaceous earth, titanium oxide, and zinc oxide. Especially, inorganic fillers of mica, talc, boron nitride, magnesium oxide, and silica are preferred.

The organic filler is not limited, and examples thereof include organic particles of polyethylene terephthalate, polybutylene terephthalate, polyethylene naphthalate, polystyrene, polyamide, polycarbonate, polyimide, polyetherketone, polyetheretherketone, polymethyl methacrylate, and the like.

For the inorganic filler and the organic filler, one may be selected from the above and used singly, or two or more may be used in combination. When two or more are combined, a combination of the inorganic filler and the organic filler may be used.

The shape of the filler is not limited and can be appropriately selected according to the purpose. For example, the inorganic filler may be a spherical inorganic filler or a nonspherical inorganic filler, but from the viewpoint of the coefficient of thermal expansion (CTE) and film strength, a nonspherical inorganic filler is preferred. The shape of the nonspherical inorganic filler can be any three-dimensional shape other than a spherical shape (generally true spherical shape), and examples of the shape of the nonspherical inorganic filler include a plate-like shape, a scale-like shape, a columnar shape, a chain-like shape, and a fibrous shape. Especially, from the viewpoint of the coefficient of thermal expansion (CTE) and film strength, plate-like and scale-like inorganic fillers are preferred, and a plate-like inorganic filler is more preferred.

In the case of a plate-like or scale-like inorganic filler, it is preferred that the average particle diameter in the planar direction be 0.05 μm or more and 20 μm or less, preferably 0.1 μm or more and 15 μm or less, desirably 0.1 μm or more and 10 μm or less, more desirably 0.1 μm or more and 7 μm or less, and it is preferred that the aspect ratio (average long axis length/average short axis length) meaning the planar direction and the thickness be 5 or more and 500 or less, preferably 20 or more and 500 or less, and desirably 40 or more and 500 or less from the viewpoint of the coefficient of thermal expansion (CTE) and film strength.

When the average particle diameter of the filler is 20 μm or less, the surface roughness of the base material film can be decreased, and a smooth coating film is easily formed.

When the aspect ratio is 5 or more, the CTE is easily sufficiently decreased.

The larger the aspect ratio is, the more easily the CTE is adjusted, but increasing the aspect ratio while decreasing the particle diameter is difficult and tends to increase the cost of the filler, and therefore the aspect ratio is desirably 500 or less.

[Measurement of Average Particle Diameter and Aspect Ratio]

The average particle diameter and aspect ratio of the inorganic filler can be obtained, for example, from the average of measured values in three or more places by observing using a scanning electron microscope (SEM) or a transmission electron microscope (TEM). The average particle diameter and aspect ratio of the inorganic filler present in the film (layer) can be obtained, for example, from the average of measured values in three or more places by embedding the film in an epoxy resin, then performing the ion milling of a film cross section using an ion milling apparatus to make a cross section observation sample, and observing the cross section of the obtained sample using a scanning electron microscope (SEM) or a transmission electron microscope (TEM).

For the average particle diameter of the organic filler, the average value when a cut surface of the base material film is observed by an electron microscope and at least 10 maximum diameters of the particles are measured can be obtained as the average dispersed particle diameter when the organic filler is dispersed in the resin of the base material film by melting and kneading, and dispersion.

The content of the filler in the base material film is preferably 1% by volume or more and 30% by volume or less, more preferably 3% by volume or more and 25% by volume or less.

<<Other Components>>

In the present invention, known additives can be optionally contained in the base material film as needed. Examples of the additives include an antioxidant, a light stabilizer, an ultraviolet absorbing agent, a crystal nucleating agent, a plasticizer, and a dispersing agent for the filler.

<<Characteristics of Base Material Film>>

The film thickness of the base material film is not limited and can be appropriately selected according to the purpose but is preferably 10 μm to 250 μm.

The surface roughness (Rz) of the base material film is not limited and can be appropriately selected according to the purpose, but considering conditions such as the type and content of the filler contained in order to provide various functions to the base material film, the surface roughness (Rz) of the base material film is 1 μm or more. On the other hand, in order to set the surface roughness (Rz) of the coating film formed on the base material film in the desired range, the surface roughness (Rz) of the base material film is preferably 10 μm or less. That is, the surface roughness (Rz) of the base material film is preferably 1 μm or more and 10 μm or less.

As used herein, the surface roughness (Rz) refers to the 10-point average roughness of a film surface. The 10-point average roughness Rz can be obtained based on JIS B 0601: 2013 (ISO 4287: 1997 Amd. 1: 2009).

[Measurement of 10-Point Average Roughness Rz]

The 10-point average roughness Rz (μm) of a surface of a sheet is obtained by measuring a roughness curve for a test piece using a laser microscope, measuring 10 samples for each from this roughness curve based on JIS B 0601: 2013 (ISO 4287: 1997 Amd. 1: 2009), and obtaining their average value.

The relative dielectric constant and dielectric loss tangent of the base material film are not limited and can be appropriately selected according to the purpose, but for reasons of a reduction in the transmission loss of electrical signals, it is preferred that the relative dielectric constant be 3.5 or less, and the dielectric loss tangent be 0.004 or less.

[Relative Dielectric Constant and Dielectric Loss Tangent]

The relative dielectric constant and dielectric loss tangent of the base material film can be measured under the conditions of a temperature of 23° C. and a frequency of 28 GHz by an open resonator method using a network analyzer MS46122B (manufactured by Anritsu) and an open resonator Fabry-Perot DPS-03 (manufactured by KEYCOM).

The coefficient of thermal expansion (CTE) of the base material film is not limited and can be appropriately selected according to the purpose but is, for example, preferably 50 ppm or less, for reasons of a decrease in the difference in the coefficient of thermal expansion from the metal to be bonded, from the viewpoint of the prevention of curling after bonding.

The measurement of the coefficient of thermal expansion can be performed by increasing temperature under load: 50 mN at a temperature increase rate: 5° C./min. from 25° C. to 250° C. at a temperature increase rate: 5° C./min with a tensile mode using a thermomechanical analyzer [manufactured by Hitachi High-Tech Corporation, product name: SII//SS7100], measuring dimensional temperature changes, and obtaining the coefficient of linear expansion from the slope in the range of 25° C. to 125° C.

The surface of the base material film may be surface-treated by corona treatment, plasma treatment, or ultraviolet treatment for reasons of the improvement of close adhesiveness to the coating film.

<Coating Film>

The surface roughness (Rz) of the coating film is 1 μm or less. The method for measuring the surface roughness (Rz) is as described in the <<Characteristics of Base Material Film>> section.

When the surface roughness (Rz) of the coating film is 1 μm or less, a metal film having a smooth surface can be formed, and in such a metal-clad laminate in which transmission loss can be reduced, a metal-clad laminate further also excellent in the close adhesiveness of the metal film can be provided, as is also clear in Examples described later.

The coating film is formed by forming a resin composition into a film and curing the resin composition.

The resin composition forming the coating film preferably includes a thermosetting resin.

Examples of the thermosetting resin includes a phenolic resin, an epoxy resin, a urea resin, a melamine resin, an unsaturated polyester resin, a polyurethane resin, a polyimide resin, a silicone resin, and a bismaleimide resin, and especially, the coating film is preferably a coating film including at least any of an epoxy resin, a polyimide resin, or a bismaleimide resin from the viewpoint of heat resistance, close adhesiveness, and dielectric characteristics.

<<Epoxy Resin>>

Examples of the epoxy resin include, but are not limited to, a bisphenol A type epoxy resin, a bisphenol F type epoxy resin, or hydrogenated products thereof; a glycidyl ester-based epoxy resin such as diglycidyl phthalate ester, diglycidyl isophthalate ester, diglycidyl terephthalate ester, glycidyl p-hydroxybenzoate ester, diglycidyl tetrahydrophthalate ester, diglycidyl succinate ester, diglycidyl adipate ester, diglycidyl sebacate ester, and triglycidyl trimellitate ester; a glycidyl ether-based epoxy resin such as ethylene glycol diglycidyl ether, propylene glycol diglycidyl ether, 1,4-butanediol diglycidyl ether, 1,6-hexanediol diglycidyl ether, trimethylolpropane triglycidyl ether, pentaerythritol tetraglycidyl ether, tetraphenyl glycidyl ether ethane, triphenyl glycidyl ether ethane, a polyglycidyl ether of sorbitol, and a polyglycidyl ether of polyglycerol; a glycidyl amine-based epoxy resin such as triglycidyl isocyanurate and tetraglycidyl diaminodiphenylmethane; and a linear aliphatic epoxy resin such as epoxidized polybutadiene and epoxidized soybean oil. A novolac type epoxy resin such as a xylene structure-containing novolac epoxy resin, a naphthol novolac type epoxy resin, a phenol novolac epoxy resin, an o-cresol novolac epoxy resin, and a bisphenol A novolac epoxy resin can also be used.

Further, as examples of the epoxy resin, a brominated bisphenol A type epoxy resin, a phosphorus-containing epoxy resin, a fluorine-containing epoxy resin, a dicyclopentadiene skeleton-containing epoxy resin, a naphthalene skeleton-containing epoxy resin, an anthracene type epoxy resin, a tertiary butyl catechol type epoxy resin, a triphenylmethane type epoxy resin, a tetraphenylethane type epoxy resin, a biphenyl type epoxy resin, a bisphenol S type epoxy resin, and the like can be used. Only one of these epoxy resins may be used, or two or more of these epoxy resins may be used in combination.

<<Bismaleimide Resin>>

Examples of the bismaleimide resin include 1-methyl-2,4-bismaleimidobenzene, N,N′-m-phenylene bismaleimide, N,N′-p-phenylene bismaleimide, N,N′-m-toluylene bismaleimide, N,N′-4,4-biphenylene bismaleimide, N,N′-4,4-(3,3′-dimethyl-biphenylene) bismaleimide, N,N′-4,4-(3,3′-dimethyldiphenylmethane) bismaleimide, N,N′-4,4-(3,3′-diethyldiphenylmethane) bismaleimide, N,N′-4,4-diphenylmethane bismaleimide, N,N′-4,4-diphenylpropane bismaleimide, N,N′-4,4-diphenyl ether bismaleimide, and N,N′-3,3-diphenyl sulfone bismaleimide.

For the bismaleimide resin, a commercial compound can also be used, and specifically, for example, BMI-3000, BMI-1500, BMI-2550, BMI-1400, BMI-2310, and BMI-3005 manufactured by DESIGNER MOLECURES Inc. can be preferably used.

Further, examples of the bismaleimide resin include modified bismaleimides obtained by modifying the above bismaleimide resins with a compound having a primary amine.

Other components such as a filler and various additives can also be contained in the coating film.

<<Filler>>

The coating film can include a filler for heat resistance improvement, fluidity control, and the like. The type of the filler is not limited and can be appropriately selected according to the purpose, and, for example, the fillers described in the <<Filler>> section, described as the filler contained in the base material film can be used.

It is preferred that the average particle diameter of the filler contained in the coating film be 0.01 μm to 20 μm, preferably 0.01 μm to 10 μm, and desirably 0.01 to 5 μm so that the surface roughness (Rz) of the coating film satisfies 1 μm or less.

The content of the filler in the coating film is preferably 0.1% by volume or more and 25% by volume or less, more preferably 1% by volume or more and 20% by volume or less.

More surface smoothness is required of the coating film than the base material film, and therefore it is preferred that the average particle diameter of the filler used be smaller than that of the base material film, and the content be lower.

<<Other Components>>

In addition to the thermosetting resin and filler, a tackifier, a flame retardant, a curing agent, a curing accelerator, a coupling agent, a thermal aging inhibitor, a leveling agent, an antifoaming agent, a pigment, a solvent, and the like can be contained in the resin composition to the extent of not affecting the function of the resin composition.

The film thickness of the coating film is not limited and can be appropriately selected according to the purpose but is, for example, preferably 1 to 100 μm, more preferably 3 to 70 μm, further preferably 5 to 50 μm, and more desirably 5 to 20 μm. When the film thickness of the coating film is 1 μm or more, sufficient uniformity to smooth the surface of the base material film can be maintained, and when the film thickness of the coating film is 100 μm or less, the peel strength between the base material film, the coating film, and the metal film can be made strong.

The film thickness of the coating film is preferably 0.8 times or more the value of the surface roughness (Rz) μm of the base material film, more preferably 1 time or more the value of the surface roughness (Rz) μm of the base material film, and further preferably 1.2 times or more the value of the surface roughness (Rz) μm of the base material film from the viewpoint of smoothing the base material film surface by the coating film, and in turn also the metal film surface, to achieve the desired lower loss of electrical signals.

The relative dielectric constant and dielectric loss tangent of the coating film are not limited and can be appropriately selected according to the purpose, but for reasons of a reduction in the transmission loss of electrical signals, it is preferred that the relative dielectric constant be 3.5 or less, and the dielectric loss tangent be 0.004 or less.

The method for measuring the relative dielectric constant and the dielectric loss tangent is as described in the <<Characteristics of Base Material Film>> section for the base material film.

The surface of the coating film may be surface-treated by corona treatment, plasma treatment, or ultraviolet treatment for reasons of the improvement of close adhesiveness to the metal film.

<<Method for Producing Coating Film>>

The coating film can be produced by forming a resin composition into a film.

The resin composition can be produced by mixing an epoxy resin, a polyimide resin, a bismaleimide resin, or the like and other components. The mixing method is not limited as long as the resin composition becomes uniform. The resin composition is preferably used in the state of a solution or a dispersion, and therefore, usually, a solvent is also used.

Examples of the solvent include alcohols such as methanol, ethanol, isopropyl alcohol, n-propyl alcohol, isobutyl alcohol, n-butyl alcohol, benzyl alcohol, ethylene glycol monomethyl ether, propylene glycol monomethyl ether, diethylene glycol monomethyl ether, and diacetone alcohol; ketones such as acetone, methyl ethyl ketone, methyl isobutyl ketone, methyl amyl ketone, cyclohexanone, and isophorone; aromatic hydrocarbons such as toluene, xylene, ethylbenzene, and mesitylene; esters such as methyl acetate, ethyl acetate, ethylene glycol monomethyl ether acetate, and 3-methoxybutyl acetate; and aliphatic hydrocarbons such as hexane, heptane, cyclohexane, and methylcyclohexane. These solvents may be used singly, or two or more of these solvents may be used in combination.

When the resin composition is a solution or a dispersion (resin varnish) including a solvent, coating on the base material film and the formation of the coating film can be smoothly performed, and a coating film having the desired thickness and surface roughness can be easily obtained.

When the resin composition includes a solvent, the solid concentration is preferably in the range of 3 to 80% by mass, more preferably 10 to 50% by mass, from the viewpoint of workability including the formation of the coating film, and the like. When the solid concentration is 80% by mass or less, the viscosity of the solution is moderate, and uniform coating is easy.

As a more specific embodiment of the method for producing the coating film, by applying a resin varnish containing the resin composition and solvent to a surface of the base material film to form a resin varnish layer, and then removing the solvent from the resin varnish layer, a coating film in a B-stage state can be formed. Here, a coating film being in a B-stage state refers to the resin composition being in an uncured state or a semi-cured state in which the resin composition begins to cure partially, and refers to a state in which the curing of the resin composition proceeds further by heating or the like.

Here, the method for applying the resin varnish on the base material film is not limited and can be appropriately selected according to the purpose, and examples of the method include a spraying method, a spin coating method, a dipping method, a roll coating method, a blade coating method, a doctor roll method, a doctor blade method, a curtain coating method, a slit coating method, a screen printing method, an ink jet method, and a dispensing method.

The coating film in the B-stage state can be further subjected to heating or the like to form a cured coating film.

<Metal Film>

The metal film is formed by at least any formation method of plating, sputtering, and vapor deposition.

By forming the metal film on the coating film having a surface roughness (Rz) of 1 μm or less by at least any formation method of plating, sputtering, and vapor deposition, a metal film having a smooth surface can be formed.

In the metal film formed by these formation methods, a finer pitch of a circuit pattern, and the formation of a high precision and fine circuit are possible.

The plating formation method and the sputtering formation method may each be separately used or may be used in combination. For example, when the plating formation method and the sputtering formation method are used in combination, a thin copper film is laid by a sputtering method, and then a copper film can be formed by an electrolytic copper plating method.

The metal constituting the metal film is not limited and can be appropriately selected according to the purpose, and examples of the metal include one selected from the group consisting of nickel, copper, silver, tin, gold, palladium, aluminum, chromium, titanium, and zinc, or an alloy including any one or more of these. Especially, copper and an alloy including copper are preferred from the viewpoint of shielding properties and economy.

Examples of the method for forming the metal film include at least any method of plating, sputtering, and vapor deposition as described above. More specific examples include a vapor-deposited film formed by physical vapor deposition (vacuum deposition, sputtering, ion beam deposition, electron beam deposition, or the like) or chemical vapor deposition, and a plating film formed by plating. Especially, a vacuum-deposited film or a sputtered film formed by a vacuum film formation method (a vacuum deposition method, a sputtering method, or the like), or a plating film formed by an electrolytic plating method is preferred in terms of excellent electrical conductivity in the planar direction.

The film thickness of the metal film is preferably 0.05 μm to 20 μm, desirably 0.1 to 15 μm, and desirably 0.5 to 10 μm from the viewpoint of ensuring sufficient transmission characteristics of electrical signals and allowing a good fine pitch of a circuit pattern.

The surface roughness (Rz) of the metal film on the surface not in contact with the coating film is not limited and can be appropriately selected according to the purpose but is, for example, preferably 0.5 μm or less for reasons of a reduction in the transmission loss of electrical signals.

<Effects of Metal-Clad Laminate>

Because a filler is contained in the base material film, and for reasons of the production of the base material film, it is difficult to smooth the surface of the base material film, but by forming the coating film having a surface roughness (Rz) of 1 μm or less on the base material film, the surface of the metal film can be smoothed, and transmission loss can be reduced. Further, the close adhesiveness between the coating film and the metal film can also be made good.

The metal film formed on the coating film is a thin metal film formed by at least any formation method of plating, sputtering, and vapor deposition, and therefore a finer pitch of a circuit pattern, and the formation of a high precision and fine circuit are possible.

<Film Thickness of Metal-Clad Laminate>

The film thickness of the metal-clad laminate is not limited and can be appropriately selected according to the purpose but is, for example, preferably 10 μm or more and 300 μm or less. When the film thickness of the metal-clad laminate is not less than the lower limit value of the range, the handling properties are excellent, and strength can be ensured. When the film thickness of the metal-clad laminate is not more than the upper limit value of the range, weight and size reduction and flexibility can be provided.

<Method for Producing Metal-Clad Laminate>

A coating film is formed on a base material film.

A metal film is formed on the surface of the coating film opposite to the base material film.

A more specific method for forming a coating film is as described in the <<Method for Producing Coating Film>> section, and by applying a resin varnish containing a resin composition and a solvent to a surface of the base material film to form a resin varnish layer, and then removing the solvent from the resin varnish layer, a coating film can be formed. The coating film can be further subjected to heating or the like to form a cured coating film.

The method for applying the resin varnish is not limited and can be appropriately selected according to the purpose, and examples of the method include a spraying method, a spin coating method, a dipping method, a roll coating method, a blade coating method, a doctor roll method, a doctor blade method, a curtain coating method, a slit coating method, a screen printing method, an ink jet method, and a dispensing method.

Examples of the method for forming a metal film include a method by a vacuum film formation method (vacuum deposition or sputtering), and a method by an electric field plating method.

In terms of being able to form a metal film having the desired film thickness and surface shape, a method of forming a vapor-deposited film by vacuum deposition, or a method of forming a plating film by electrolytic plating, or a method of forming a sputtered film by sputtering, or electrolytic plating can be performed after sputtering to form a metal film in which sputtering and plating are used in combination.

When the metal-clad laminate of the present invention is a metal-clad laminate in which a coating film and a metal film are provided on each of both surfaces of a base material film, as shown in FIG. 2, it is possible to form a coating film and a metal film on one surface of a base material film by the above-described method and subsequently form a coating film and a metal film on the other surface of the base material film by the same method. Alternatively, a method may be used in which coating films on both sides are formed together on a base material film, and next, metal films disposed on the coating films are also formed together on both sides.

When for the base material film and/or the coating film, a base material film or a coating film surface-treated by corona treatment, plasma treatment, ultraviolet treatment, or the like is used, it is recommended, for example, that a base material film be provided, then the surface of the provided base material film be surface-treated, and a coating film be formed on the surface-treated base material film by the above-described method. It is recommended that after the coating film is formed, the coating film surface be surface-treated, and subsequently a metal film be formed by the above-described method.

### EXAMPLES

The present invention will be described in more detail below by giving Examples, but the scope of the present invention is not limited to these Examples. In the following, parts and % are based on mass unless otherwise noted.

### Example 1

### <Base Material Film>

A polyether ether ketone (PEEK) resin (Victrex Granules 450G: manufactured by Victrex) and synthetic mica (Micromica MK100: manufactured by Katakura & Co-op Agri Corporation) were mixed so that the synthetic mica was 15% by volume, and the mixture was extruded by a twin-screw extruder to make pellets. The average particle diameter of the synthetic mica used was 4.9 μm, and the aspect ratio was in the range of 30 to 50.

The obtained pellets were charged into a single-screw extruder with a T die having a width of 900 mm, melted and kneaded, and continuously extruded from the T die to obtain a PEEK film having a thickness of 100 μm (Rz of film: 6.4 μm, CTE 30 ppm).

<Making of Resin Composition 1 Forming Coating Film>

An alkyl bismaleimide resin (BMI-3000: manufactured by Desiner Molecules Inc) was dissolved in toluene so that the solid content was 50% by mass. Subsequently, the solution was diluted with methyl isobutyl ketone so that the solid content was 25% by mass. A peroxide (PERCUMYL D: manufactured by NOF CORPORATION) was added so as to be in the proportion of 2% by mass to the solid content. These were mixed to make an application solution 1.

<Making of Copper-Clad Laminate>

The surface of the PEEK film made was corona-treated. The application solution 1 obtained above was applied on the surface-treated PEEK film. Subsequently, the coating film was dried. The film thickness after the drying was 7 μm.

Next, the base material film with the coating film was placed in an oven at 200° C. for 1 h to cure the coating film.

The Rz of the coating film surface at this time was 0.35 μm.

A film of copper (film thickness 0.1 μm) was formed on the cured coating film by sputtering.

The Rz of the metal layer including the copper film was 0.15 μm.

When for the metal-clad laminate (copper-clad laminate) of Example 1 obtained in this manner, the peel strength of the metal layer was measured by the following measurement method, it was 7 N/cm or more.

### [Peel Strength]

The peel strength of the copper-clad laminate was measured at a peel rate of 300 mm/min by a T-peel test according to the method specified in JIS K6854-3: 1999.

For the metal-clad laminate (copper-clad laminate) of Example 1, transmission loss was measured by the following measurement method, and the transmission characteristics were evaluated by the following criteria.

### [Transmission Loss Measurement Method]

A microstrip line substrate (line length 50 mm) whose impedance was adjusted at 50Ω was made from the copper-clad laminate, and the S parameter (S21) at 20 GHz was measured by a network analyzer.

### [Evaluation Criteria]

Good (a transmission loss of 4 dB/cm or less: 20 GHz)

Poor (a transmission loss of greater than 4 dB/cm: 20 GHz)

Various measurement results for the base material film, the coating film, and the metal film and the measurement and evaluation results of the characteristics (peel strength and transmission characteristics) of the copper-clad laminate for the copper-clad laminate of Example 1 are shown in Table 1.

### Example 2 to Example 7

The copper-clad laminates of Example 2 to Example 7 were made in the same manner as Example 1 except that in Example 1, the conditions of the coating film were changed as shown in Table 1.

An application solution 2 and an application solution 3 used in Example 2 to Example 7 were made as follows.

<Making of Resin Composition 2 Forming Coating Film>

A dicyclopentadiene type low dielectric epoxy resin (HP7200H: manufactured by DIC) was dissolved in toluene so that the solid content was 50% by mass. Subsequently, the solution was diluted with methyl isobutyl ketone so that the solid content was 25% by mass.

An alkyl bismaleimide resin (BMI-3000: manufactured by Desiner Molecules Inc) and 2-methylimidazole (2MZ: manufactured by SHIKOKU CHEMICALS CORPORATION) were added so as to be in the proportions of 20 parts by mass and 2% by mass, respectively, to the solid content of the dicyclopentadiene type low dielectric epoxy resin. These were mixed to make the application solution 2.

<Making of Resin Composition 3 Forming Coating Film>

An alkyl bismaleimide resin (BMI-3000: manufactured by Desiner Molecules Inc) was dissolved in toluene so that the solid content was 50% by mass. Subsequently, the solution was diluted with methyl isobutyl ketone so that the solid content was 25% by mass. Synthetic mica (Micromica MK100DS: manufactured by Katakura & Co-op Agri Corporation: average particle diameter 3.3 μm, aspect ratio in the range of 30 to 50) and a peroxide (PERCUMYL D: manufactured by NOF CORPORATION) were added so as to be in the proportions of 10% by volume and 2% by mass, respectively, to the solid content of the alkyl bismaleimide resin. These were mixed to make the application solution 3.

For the copper-clad laminates made in Example 2 to Example 7, the same measurement as Example 1 was performed.

Various measurement results for the base material film, the coating film, and the metal film and the measurement and evaluation results of the characteristics of the copper-clad laminate for the copper-clad laminates of Example 2 to Example 7 are shown in Table 1.

### Comparative Example 1

For a PEEK film made by the same method as Example 1, the surface of the PEEK film was corona-treated.

A film of copper (film thickness 0.1 μm) was formed on the surface-treated PEEK film by sputtering.

The Rz of the metal layer including the copper film was 6.2 μm.

When for the metal-clad laminate (copper-clad laminate) of Comparative Example 1 obtained in this manner, the peel strength of the metal layer was measured by the same method as Example 1, it was 2 N/cm or less.

Various measurement results for the base material film and the metal film and the measurement and evaluation results of the characteristics of the copper-clad laminate for the copper-clad laminate of Comparative Example 1 are shown in Table 1.

### Comparative Example 2 to Comparative Example 5

The copper-clad laminates of Comparative Example 2 to Comparative Example 5 were made in the same manner as Example 1 except that in Example 1, the conditions of the coating film were changed as shown in Table 1.

For the copper-clad laminates made in Comparative Example 2 to Comparative Example 5, the same measurement as Example 1 was performed.

Various measurement results for the base material film, the coating film, and the metal film and the measurement and evaluation results of the characteristics of the copper-clad laminate for the copper-clad laminates of Comparative Example 2 to Comparative Example 5 are shown in Table 1.

TABLE 1

| | Base material film | | | | Coating film | | | | | Metal | Characteristics | |
|---|---|---|---|---|---|---|---|---|---|---|---|---|
| | | | Relative | Dielectric | | | | Relative | Dielectric | film | Peel | |
| | | Rz | dielectric | loss | | Thickness | Rz | dielectric | loss | Rz | strength | Transmission |
| | Type | (μm) | constant | tangent | Type | (μm) | (μm) | constant | tangent | (μm) | (N/cm) | characteristics |
| Example 1 | PEEK | 6.4 | 3.4 | 0.003 | Application | 7 | 0.35 | 2.8 | 0.0025 | 0.15 | 7 | Good |
| | Mica | | | | solution 1 | | | | | | | |
| Example 2 | PEEK | 6.4 | 3.4 | 0.003 | Application | 6.5 | 0.5 | 2.8 | 0.0025 | 0.3 | 7 | Good |
| | Mica | | | | solution 1 | | | | | | | |
| Example 3 | PEEK | 6.4 | 3.4 | 0.003 | Application | 5.2 | 0.95 | 2.8 | 0.0025 | 0.48 | 8 | Good |
| | Mica | | | | solution 1 | | | | | | | |
| Example 4 | PEEK | 6.4 | 3.4 | 0.003 | Application | 21 | 0.04 | 2.8 | 0.0025 | 0.12 | 5 | Good |
| | Mica | | | | solution 1 | | | | | | | |
| Example 5 | PEEK | 6.4 | 3.4 | 0.003 | Application | 7 | 0.35 | 4 | 0.005 | 0.16 | 8 | Good |
| | Mica | | | | solution 2 | | | | | | | |
| Example 6 | PEEK | 6.4 | 3.4 | 0.003 | Application | 5.2 | 0.95 | 4 | 0.005 | 0.49 | 9 | Good |
| | Mica | | | | solution 2 | | | | | | | |
| Example 7 | PEEK | 6.4 | 3.4 | 0.003 | Application | 7 | 0.51 | 3.4 | 0.0023 | 0.35 | 8 | Good |
| | Mica | | | | solution 3 | | | | | | | |
| Comparative | PEEK | 6.4 | 3.4 | 0.003 | — | — | — | — | — | 6.2 | 2 | Poor |
| Example 1 | Mica | | | | | | | | | | | |
| Comparative | PEEK | 6.4 | 3.4 | 0.003 | Application | 4.6 | 1.2 | 2.8 | 0.0025 | 0.75 | 8 | Poor |
| Example 2 | Mica | | | | solution 1 | | | | | | | |
| Comparative | PEEK | 6.4 | 3.4 | 0.003 | Application | 4.5 | 1.2 | 4 | 0.005 | 0.71 | 9 | Poor |
| Example 3 | Mica | | | | solution 2 | | | | | | | |
| Comparative | PEEK | 6.4 | 3.4 | 0.003 | Application | 3.5 | 2.0 | 2.8 | 0.0025 | 1.8 | 9 | Poor |
| Example 4 | Mica | | | | solution 1 | | | | | | | |
| Comparative | PEEK | 6.4 | 3.4 | 0.003 | Application | 3.5 | 2.0 | 4 | 0.005 | 1.9 | 9 | Poor |
| Example 5 | Mica | | | | solution 2 | | | | | | | |

The metal films in the metal-clad laminates of the present invention made in the Examples have smooth surfaces, and therefore the metal-clad laminates of the present invention are metal-clad laminates in which transmission loss can be reduced. Further, as also shown in the results in Table 1, the metal-clad laminates of the present invention are excellent in the close adhesiveness of the metal film to the coating film and the base material film.

### INDUSTRIAL APPLICABILITY

The metal-clad laminate of the present invention can be preferably used for the production of FPC-related products for electronic equipment such as smartphones, cellular phones, optical modules, digital cameras, game machines, notebook computers, and medical instruments.

1. A metal-clad laminate comprising a coating film and a metal film laminated on a base material film in this order, wherein
the metal film is a metal film formed by at least any formation method of plating, sputtering, and vapor deposition, and
a surface roughness (Rz) of the coating film is 1 μm or less.

2. The metal-clad laminate according to claim 1, wherein the coating film and the metal film are laminated on each of both sides of the base material film, and wherein the metal-clad laminate comprises a metal film, a coating film, a base material film, a coating film, and a metal film laminated in order.

3. The metal-clad laminate according to claim 1, wherein a surface roughness (Rz) of the base material film is 1 μm or more and 10 μm or less.

4. The metal-clad laminate according to claim 1, wherein a surface roughness (Rz) of the metal film is 0.5 μm or less.

5. The metal-clad laminate according to claim 1, wherein the coating film comprises a thermosetting resin.

6. The metal-clad laminate according to claim 1, wherein the coating film comprises at least any of an epoxy resin, a polyimide resin, or a bismaleimide resin.

7. The metal-clad laminate according to claim 1, wherein a film thickness of the coating film is not less than the surface roughness (Rz) of the base material film×0.8.

8. The metal-clad laminate according to claim 1, wherein a film thickness of the metal film is 0.05 μm or more and 10 μm or less.

9. The metal-clad laminate according to claim 1, wherein a relative dielectric constant of the base material film is 3.5 or less, and a dielectric loss tangent of the base material film is 0.004 or less.

10. The metal-clad laminate according to claim 1, wherein a relative dielectric constant of the coating film is 3.5 or less, and a dielectric loss tangent of the coating film is 0.004 or less.

11. The metal-clad laminate according to claim 1, wherein a coefficient of thermal expansion (CTE) of the base material film is 50 ppm or less.

12. The metal-clad laminate according to claim 1, wherein the base material film is a liquid crystal polymer (LCP) film, a polyether ether ketone (PEEK) film, a tetrafluoroethylene perfluoroalkyl (PFA) film, or a polyphenylene sulfide (PPS) film.

13. The metal-clad laminate according to claim 1, wherein the base material film contains a filler.

14. The metal-clad laminate according to claim 13, wherein the filler comprises at least any of mica, talc, boron nitride (BN), magnesium oxide, and silica.

15. The metal-clad laminate according to claim 13, wherein the filler has a plate-like shape.

16. The metal-clad laminate according to claim 13, wherein an aspect ratio of the filler is 5 or more and 500 or less.

17. The metal-clad laminate according to claim 13, wherein an average particle diameter of the filler is 20 μm or less.

18. The metal-clad laminate according to claim 1, wherein the coating film contains a filler.

19. The metal-clad laminate according to claim 1, wherein the metal film is a metal film of copper.

20. The metal-clad laminate according to claim 1, wherein a surface of the base material film, the coating film, or the base material film and the coating film is corona-treated, plasma-treated, or ultraviolet-treated.
